(19) United States
(12) Patent Application Publication
(10) Pub. No.: US 2010/0182013 A1
(43) Pub. Date: Jul. 22, 2010

(54) PROBING APPARATUS WITH TEMPERATURE-ADJUSTING MODULES FOR TESTING SEMICONDUCTOR DEVICES

(75) Inventor: CHOON LEONG LOU, HSINCHU CITY (TW)

Correspondence Address: WPAT, PC;INTELLECTUAL PROPERTY ATTORNEYS, 2030 MAIN STREET, SUITE 1300, IRVINE, CA, 92614, US

(73) Assignee: STAR TECHNOLOGIES INC., HSINCHU CITY (TW)

(21) Appl. No.: 12/418,021

(22) Filed: Apr. 3, 2009

(30) Foreign Application Priority Data
Jan. 16, 2009 (TW) 098101472

(51) Int. Cl. G01R 31/02

(52) U.S. Cl. 324/555

(57) ABSTRACT

A probing apparatus for testing semiconductor devices comprises an upper guiding plate having a plurality of upper guiding holes, a bottom guiding plate having a plurality of bottom guiding holes, a plurality of vertical probes disposed between the upper guiding holes of the upper guiding plate and the bottom guiding holes of the bottom guiding plate, and a temperature-adjusting module including at least one flow line configured to direct a fluid into a space between the upper guiding plate and the bottom guiding plate.

### BACKGROUND OF THE INVENTION

(A) Field of the Invention

The present invention relates to a probing apparatus for testing semiconductor devices, and more particularly, to a probing apparatus equipped with a temperature-adjusting module to transfer heat out using pressurized fluid.

(B) Description of the Related Art

Generally, it is necessary to test the electrical characteristics of integrated circuit devices at the wafer level to check whether the integrated circuit device satisfies the product specification. Integrated circuit devices with electrical characteristics satisfying the specification are selected for the subsequent packaging process, and the other devices are discarded to avoid additional packaging cost. Another electrical property test will be performed on the integrated circuit device after the packaging process is completed to screen out the below-standard devices and increase the product yield.

There are two major types of probes according to the prior art, i.e., the cantilever probe and the vertical probe. The cantilever probe provides appropriate vertical displacement when the probe tip contacts an integrated circuit device under test via a cantilever contact structure designed to prevent the integrated circuit device under test from being exposed to excessive probe pressure applied by the probe tip. However, the cantilever contact structure occupies a larger planar space in a matrix array probing, which constrains the cantilever probe from being arranged in a fine pitch manner corresponding to an integrated circuit device with a high density of pins, and therefore the cantilever probe cannot be applied to the testing of the integrated circuit devices with high density of pins. Instead, the vertical probe offers the vertical displacement required by the probe tip to contact the integrated circuit device under test using the deformation of the probe body itself, and can be arranged in a very fine pitch manner corresponding to the integrated circuit devices under test with high density of pins.

U.S. Pat. No. 5,977,787 discloses a vertical probe assembly for checking the electronic properties of integrated circuit devices. The vertical probe assembly includes a buckling beam, an upper plate and a bottom plate. The vertical probe is used to contact the pad of the device under test to build a path for propagating the test signal, and the probe can bend to relieve the stress generated as the probe contacts the device under test. The upper plate and the bottom plate have holes to hold the buckling beam, and the hole of the upper plate deviates from the hole of the bottom plate, i.e., it is not positioned in a mirror image manner. In addition, frequent bending of the vertical probe is likely to generate metal fatigue and the lifetime of the vertical probe is thereby shortened.

U.S. Pat. No. 5,952,843 discloses a vertical probe assembly for checking the electronic properties of integrated circuit devices. The vertical probe assembly includes a bend beam, an upper plate and a bottom plate. The vertical probe has an S-shaped bend portion configured to relieve the stress generated as the probe contacts the device under test. In addition, the upper plate and the bottom plate have holes to hold the buckling beam, and the holes of the upper plate and the bottom plate are positioned in a mirror image manner, without deviation from alignment.

U.S. Pat. No. 6,476,626 discloses a probe contact system capable of adjusting distances between tips of the contactors and contact targets with a simple and low cost module. The probe contact system uses a POGO pin to relieve the stress generated as the probe contacts the device under test. The POGO pin has a spring to relieve the stress so as to prevent the POGO pin from over-bending and generating metal fatigue.

U.S. Pat. No. 6,621,710 discloses a modular probe card assembly comprising a silicon substrate with probes modularly assembled on a main board. The silicon substrate has probes fabricated by the micro-electron-mechanical technique, which can fabricate the probe at very fine size and pitch. Consequently, the modular probe card assembly can be applied to integrated circuit devices with high-density pads.

During the testing processes such as the reliability test, the semiconductor devices such as the integrated circuit devices are heated to a predetermined temperature, and heat is transferred to the test environment where the probe card is positioned by thermal radiation or by thermal conduction through the tip of the probe, i.e., the temperature of the test environment increases. The increasing temperature causes the physical or material properties of parts or modules in the test environment to change; for example the thermal expansion property causes the material to undergo strain. As a result, the increasing temperature may interrupt the testing or influence the accuracy of the test. In addition, the heat transfer into a test head above the circuit board may also influence the temperature range at which the test instruments or parts within the test head to give results of lower accuracy due to tests being carried out at a temperature outside the specification of the test units.

### SUMMARY OF THE INVENTION

One aspect of the present invention provides a probing apparatus equipped with a temperature-adjusting module to transfer heat out using a pressurized fluid.

A probing apparatus for testing semiconductor devices according to this aspect of the present invention comprises an upper guiding plate having a plurality of upper guiding holes, a bottom guiding plate having a plurality of bottom guiding holes, a plurality of vertical probes disposed between the upper guiding holes of the upper guiding plate and the bottom guiding holes of the bottom guiding plate, and a temperature-adjusting module including at least one flow line configured to direct a fluid into a space between the upper guiding plate and the bottom guiding plate.

Another aspect of the present invention provides a probing apparatus for testing semiconductor devices comprising an upper guiding plate having a plurality of upper guiding holes, a bottom guiding plate having a plurality of bottom guiding holes and an upper surface facing the upper guiding plate, a plurality of elastic probes disposed between the upper guiding holes of the upper guiding plate and the bottom guiding holes of the bottom guiding plate, and a cleaning module including at least one flow line configured to direct a cleaning fluid to the upper surface of the bottom guiding plate.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives and advantages of the present invention will become apparent upon reading the following description and upon reference to the accompanying drawings in which:

FIG. 1 illustrates a probing apparatus for testing semiconductor devices according to one embodiment of the present invention;

FIG. 2 illustrates a probing apparatus for testing semiconductor devices according to another embodiment of the present invention;

FIG. 3 and FIG. 4 illustrate a probing apparatus for testing semiconductor devices according to another embodiment of the present invention;

FIG. 5 and FIG. 6 illustrate a probing apparatus for testing semiconductor devices according to another embodiment of the present invention; and

FIG. 7 illustrates a probing apparatus for testing semiconductor devices according to another embodiment of the present invention.

### DETAILED DESCRIPTION OF THE INVENTION

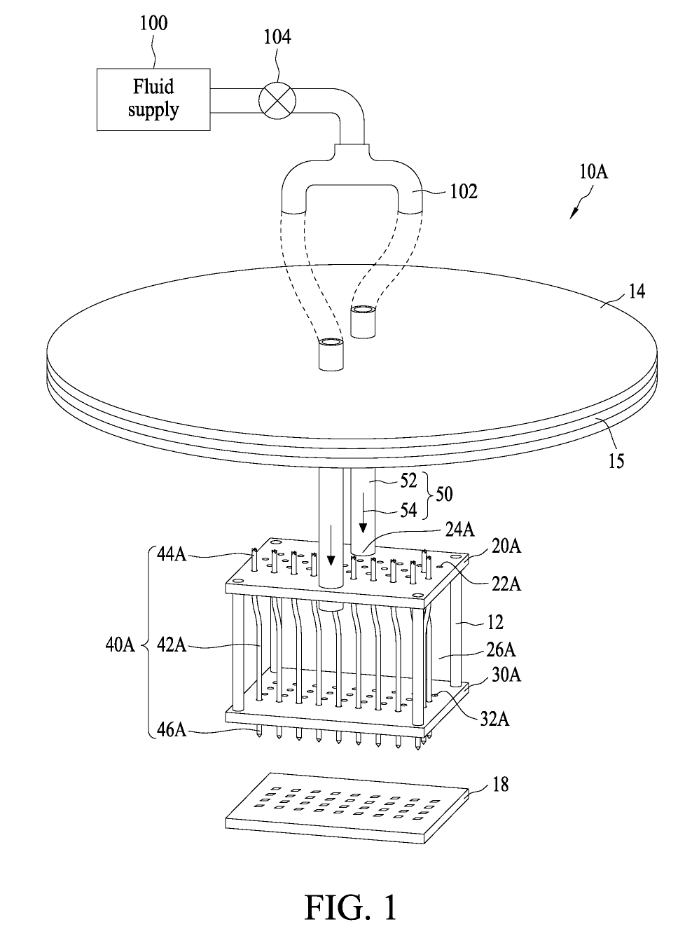

FIG. 1 illustrates a probing apparatus 10A for testing semiconductor devices 18 according to one embodiment of the present invention. The probing apparatus 10A comprises a printed circuit board 14 including a plurality of stacked laminates 15 and conductive strips embedded therein (or on the surface), an upper guiding plate 20A having a plurality of upper guiding holes 22A, a bottom guiding plate 30A having a plurality of bottom guiding holes 32A, a plurality of vertical probes 40A disposed between the upper guiding holes 22A of the upper guiding plate 20A and the bottom guiding holes 32A of the bottom guiding plate 30A, a plurality of spacers 12 disposed between the upper guiding plate 20A and the bottom guiding plate 30A, and a temperature-adjusting module 50 including at least one flow line 52 configured to direct a pressurized fluid 54 into a space 26A between the upper guiding plate 20A and the bottom guiding plate 30A.

Each of the vertical probes 40A includes a connector end 44A configured to contact a conductor on the bottom surface of the printed circuit board 14, a tip end 46A configured to contact a conductor of the semiconductor devices 18 such as the integrated circuit devices under test, and a buckling section 42A disposed between the connector end 44A and the tip end 46A. In addition, the flow line 52 is coupled to an outlet 102 of a fluid supply 100 such that the pressurized fluid 54 is provided to the space 26A through the flow line 52. In addition, a control valve 104 may be used to control the flow of the pressurized fluid 54 from the fluid supply 100. The control valve 104 may be controlled manually or by an external controller to control the flow of the pressurized fluid 54 from the fluid supply 100 to the supply inlet 102.

During the testing processes such as the reliability test, the semiconductor devices 18 are heated to a predetermined temperature, and heat is transferred to the space 26A between the upper guiding plate 20A and the bottom guiding plate 30A by thermal radiation or by thermal conduction through the tip end 46A of the probe 40A. The increasing temperature causes the physical or material properties of the probes 40A to change; for example the thermal expansion property causes the probes 40A to undergo strain. As a result, the increasing temperature may influence the position accuracy of the probes 40A in relation to the semiconductor device 18. To solve this problem, one embodiment of the present invention uses the temperature-adjusting module 50 to transfer heat out by directing the pressurized cooling fluid 54 into the space 26A. In one embodiment of the present invention, the flow line 52 of the temperature-adjusting module 50 is configured to direct the pressurized cooling fluid 54 including gas, liquid nitrogen or the combination thereof into the space 26A between the upper guiding plate 20A and the bottom guiding plate 30A through an aperture 24A of the upper guiding plate 20A.

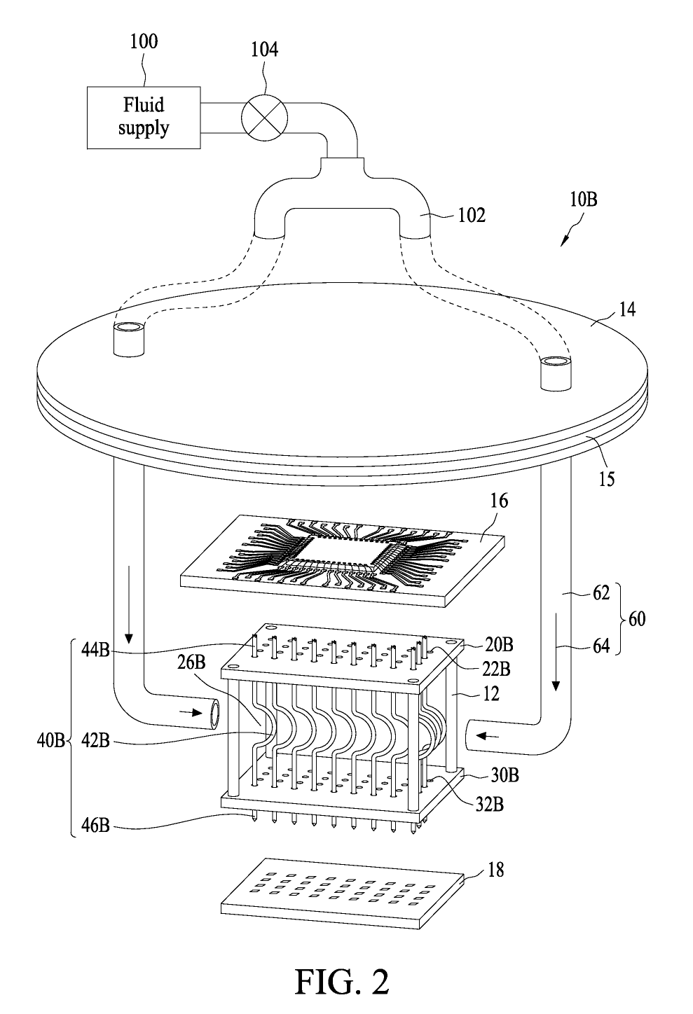

FIG. 2 illustrates a probing apparatus 10B for testing semiconductor devices 18 according to another embodiment of the present invention. The probing apparatus 10B comprises a printed circuit board 14 including a plurality of stacked laminates 15 and conductive strips embedded therein (or on the surface), an upper guiding plate 20B having a plurality of upper guiding holes 22B, a bottom guiding plate 30B having a plurality of bottom guiding holes 32B, a plurality of vertical probes 40B disposed between the upper guiding holes 22B of the upper guiding plate 20B and the bottom guiding holes 32B of the bottom guiding plate 30B, a plurality of spacers 12 disposed between the upper guiding plate 20B and the bottom guiding plate 30B, and a temperature-adjusting module 60 including at least one flow line 62 configured to direct a pressurized fluid 64 into a space 26B between the upper guiding plate 20B and the bottom guiding plate 30B.

In addition, a connector plate 16 is sandwiched between the upper guiding plate 20B and the printed circuit board 14, and has a plurality of conductive patterns configured to electrically connect the vertical probes 40B and the printed circuit board 14. Furthermore, each of the vertical probes 40B includes a connector end 44B configured to connect to the printed circuit board 14 via the connector plate 16, a tip end 46B configured to contact a conductor of the semiconductor devices 18 under test, and a spring section 42B disposed between the connector end 44B and the tip end 46B. The flow line 62 is coupled to an outlet 102 of a fluid supply 100 such that the pressurized fluid 64 is proved to the space 26B through the flow line 62. In addition, a control valve 104 may be used to control the flow of the pressurized fluid 64 from the fluid supply 100. The control valve 104 may be controlled manually or by an external controller to control the flow of the pressurized fluid 64 from the fluid supply 100 to the supply inlet 102.

During the testing processes such as the reliability test, the semiconductor devices 18 are heated to a predetermined temperature, and heat is transferred to the space 26B between the upper guiding plate 20B and the bottom guiding plate 30B by thermal radiation or by thermal conduction through the tip end 46B of the probe 40B. The increasing temperature causes the physical or material properties of the probes 40B to change; for example the thermal expansion property causes the probes 40B to undergo strain. As a result, the increasing temperature may influence the position accuracy of the probes 40B in relation to the semiconductor device 18. To solve this problem, one embodiment of the present invention uses the temperature-adjusting module 60 to transfer heat out by directing the pressurized cooling fluid 64 into the space 26B. In one embodiment of the present invention, the flow line 62 of the temperature-adjusting module 60 is configured to direct the pressurized cooling fluid 64 including gas, liquid nitrogen or the combination thereof into the space 26B through the side of the space 26B.

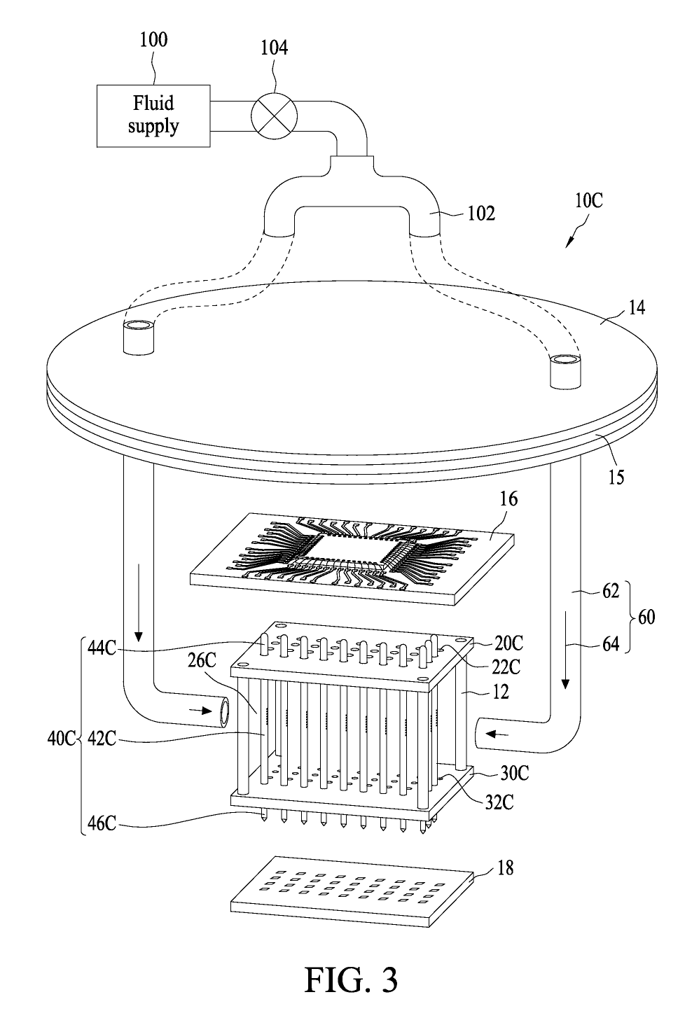

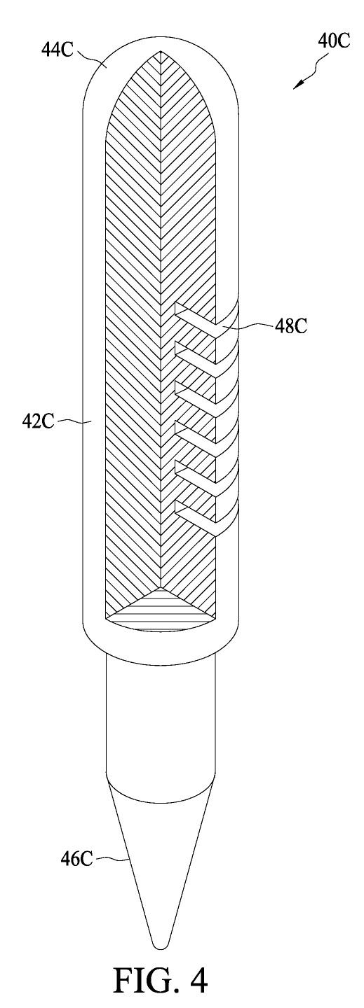

FIG. 3 and FIG. 4 illustrate a probing apparatus 10C for testing semiconductor devices 18 according to another embodiment of the present invention. The probing apparatus 10C comprises a printed circuit board 14 including a plurality of stacked laminates 15 and conductive strips embedded therein (or on the surface), an upper guiding plate 20C having a plurality of upper guiding holes 22C, a bottom guiding plate 30C having a plurality of bottom guiding holes 32C, a plurality of vertical probes 40C disposed between the upper guiding holes 22C of the upper guiding plate 20C and the bottom guiding holes 32C of the bottom guiding plate 30C, a plurality of spacers 12 disposed between the upper guiding plate 20C and the bottom guiding plate 30C, and a temperature-adjusting module 60 including at least one flow line 62 configured to direct a pressurized fluid 64 into a space 26C between the upper guiding plate 20C and the bottom guiding plate 30C.

In addition, a connector plate 16 is sandwiched between the upper guiding plate 20C and the printed circuit board 14, and has a plurality of conductive patterns configured to electrically connect the vertical probes 40C and the printed circuit board 14. Furthermore, each of the vertical probes 40C includes a connector end 44C configured to connect to the printed circuit board 14 via the connector plate 16, a tip end 46C configured to contact a conductor of the semiconductor devices 18 under test, a linear body 42C disposed between the connector end 44C and the tip end 46C, and at least one slot 48C positioned on the linear body 42C. The flow line 62 is coupled to an outlet 102 of a fluid supply 100 such that the pressurized fluid 64 is proved to the space 26C through the flow line 62. In addition, a control valve 104 may be used to control the flow of the pressurized fluid 64 from the fluid supply 100. The control valve 104 may be controlled manually or by an external controller to control the flow of the pressurized fluid 64 from the fluid supply 100 to the supply inlet 102.

During the testing processes such as the reliability test, the semiconductor devices 18 are heated to a predetermined temperature, and heat is transferred to the space 26C between the upper guiding plate 20C and the bottom guiding plate 30C by thermal radiation or by thermal conduction through the tip end 46C of the probe 40C. The increasing temperature causes the physical or material properties of the probes 40C to change; for example the thermal expansion property causes the probes 40C to undergo strain. As a result, the increasing temperature may influence the position accuracy of the probes 40C in relation to the semiconductor device 18. To solve this problem, one embodiment of the present invention uses the temperature-adjusting module 60 to transfer heat out by directing the pressurized cooling fluid 64 into the space 26C. In one embodiment of the present invention, the flow line 62 of the temperature-adjusting module 60 is configured to direct the pressurized cooling fluid 64 including gas, liquid nitrogen or the combination thereof into the space 26C through the side of the space 26C.

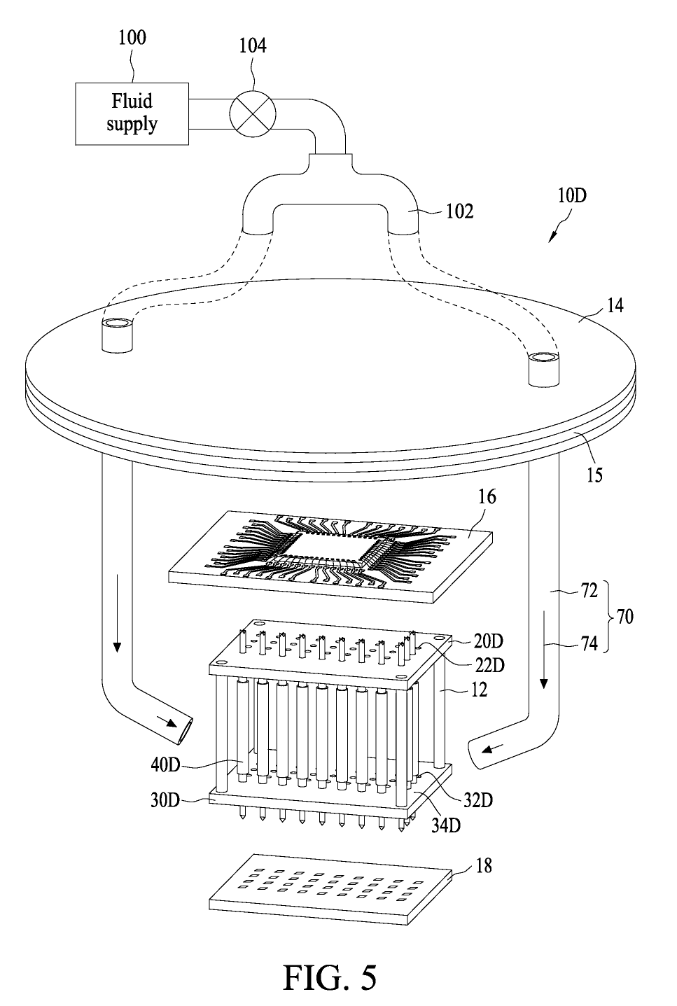

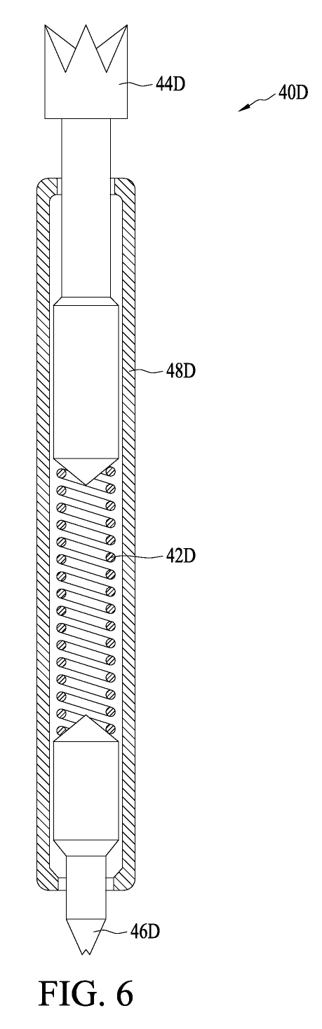

FIG. 5 and FIG. 6 illustrate a probing apparatus 10D for testing semiconductor devices 18 according to another embodiment of the present invention. The probing apparatus 10D comprises a printed circuit board 14 including a plurality of stacked laminates 15 and conductive strips embedded therein (or on the surface), an upper guiding plate 20D having a plurality of upper guiding holes 22D, a bottom guiding plate 30D having a plurality of bottom guiding holes 32D, a plurality of elastic probes 40D such as POGO pins disposed between the upper guiding holes 22D of the upper guiding plate 20D and the bottom guiding holes 32D of the bottom guiding plate 30D, a plurality of spacers 12 disposed between the upper guiding plate 20D and the bottom guiding plate 30D, and a cleaning module 70 including at least one flow line 72 configured to direct a cleaning fluid 74 onto to an upper surface 34D of the bottom guiding plate 30D.

In addition, a connector plate 16 is sandwiched between the upper guiding plate 20D and the printed circuit board 14, and has a plurality of conductive patterns configured to electrically connect the elastic probes 40D and the printed circuit board 14. Furthermore, each of the elastic probes 40D includes a housing 48D, a spring 42D with two ends positioned in the housing 48D, a connecting pin 44D configured to connect to the printed circuit board 14 via the connector plate 16, and a connecting pin 46D configured to contact a conductor of the semiconductor devices 18 under test. The flow line 72 is coupled to an outlet 102 of a fluid supply 100 such that the pressurized fluid 74 is proved to the upper surface 34D through the flow line 72. In addition, a control valve 104 may be used to control the flow of the pressurized fluid 74 from the fluid supply 100. The control valve 104 may be controlled manually or by an external controller to control the flow of the pressurized fluid 74 from the fluid supply 100 to the supply inlet 102.

During the electrical testing processes, the elastic probes 40D contact the different semiconductor devices 18 to form the electrical connection between the devices 18 under test and the circuit board 14, and the spring 42D repeatedly expands and contracts to relieve the stress generated as the elastic probes 40D contacts the devices 18 under test. However, repeated expanding and contracting of the spring 42D generate flakes or particles on the upper surface 34D of the bottom guiding plate 30D, which may form short circuits between the adjacent elastic probes 40D. To solve this problem, one embodiment of the present invention uses the cleaning module 70 to remove the flakes or particles from the upper surface 34D by blowing the pressurized cleaning fluid 74 toward the upper surface 34D. In one embodiment of the present invention, the flow line 72 of the cleaning module 70 is configured to direct the pressurized cleaning fluid 74 including gas, liquid or the combination thereof onto the upper surface 34D through the side of the space 26D between the upper guiding plate 20D and the bottom guiding plate 30D.

The upper guiding plate 20D, the bottom guiding plate 30D, and the elastic probes 40D serve as a probe head for testing the semiconductor devices 18. In addition, the upper guiding plate 20D, the bottom guiding plate 30D, and the elastic probes 40D may serve as a probe fixture, which can be a form of IC socket. The probe fixture may be used to electrically an electronic device under test connected to the connecting pin 44D of the elastic probes 40D and a printed circuit board connected to the connecting pin 46D of the elastic probes 40D. The cleaning module 70 including the flow line 72 is configured to direct the cleaning fluid 74 onto to an upper surface 34D of the bottom guiding plate 30D so as to remove flakes or particles on the upper surface 34D.

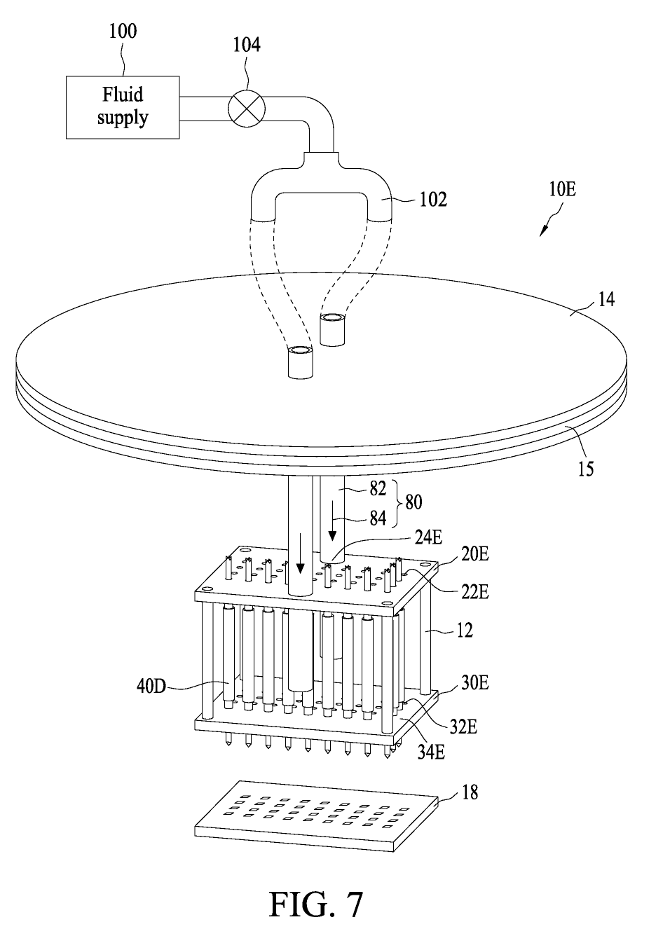

FIG. 7 illustrates a probing apparatus 10E for testing semiconductor devices 18 according to one embodiment of the present invention. The probing apparatus 10E comprises a printed circuit board 14 including a plurality of stacked laminates 15 and conductive strips embedded therein (or on the surface), an upper guiding plate 20E having a plurality of upper guiding holes 22E, a bottom guiding plate 30E having a plurality of bottom guiding holes 32E, a plurality of elastic probes 40E disposed between the upper guiding holes 22E of the upper guiding plate 20E and the bottom guiding holes 32E of the bottom guiding plate 30E, a plurality of spacers 12 disposed between the upper guiding plate 20E and the bottom guiding plate 30E, and a cleaning module 80 including at least one flow line 82 configured to direct a pressurized fluid 84 onto the upper surface 34E of the bottom guiding plate 34E. The flow line 82 is coupled to an outlet 102 of a fluid supply 100 such that the pressurized fluid 84 is proved to the upper surface 34E through the flow line 82. In addition, a control valve 104 may be used to control the flow of the pressurized fluid 84 from the fluid supply 100. The control valve 104 may be controlled manually or by an external controller to control the flow of the pressurized fluid 84 from the fluid supply 100 to the supply inlet 102.

During the electrical testing processes, the elastic probes 40D contact the different semiconductor devices 18 to form the electrical connection between the devices 18 under test and the circuit board 14, and the spring 42D repeatedly expands and contracts to relieve the stress generated as the elastic probes 40D contact the devices 18 under test. However, repeated expanding and contracting of the spring 42D generate flakes or particles on the upper surface 34E of the bottom guiding plate 30E, which may form short circuits between the adjacent elastic probes 40D. To solve this problem, one embodiment of the present invention uses the cleaning module 80 to remove the flakes or particles from the upper surface 34E by blowing the pressurized cleaning fluid 84 onto the upper surface 34E. In one embodiment of the present invention, the flow line 82 of the cleaning module 80 is configured to direct the pressurized cleaning fluid 84 including gas, liquid or the combination thereof onto the upper surface 34E through an aperture 24E of the upper guiding plate 20E.

The upper guiding plate 20E, the bottom guiding plate 30E, and the elastic probes 40E serve as a probe head for testing the semiconductor devices 18. In addition, the upper guiding plate 20E, the bottom guiding plate 30E, and the elastic probes 40D may serve as a probe fixture, which can be a form of IC socket. The probe fixture may be used to electrically an electronic device under test connected to the connecting pin 44D of the elastic probes 40D and a printed circuit board connected to the connecting pin 46D of the elastic probes 40D. The cleaning module 80 including the flow line 82 is configured to direct the cleaning fluid 84 onto to an upper surface 34E of the bottom guiding plate 30E so as to remove flakes or particles on the upper surface 34E.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A probing apparatus for testing semiconductor devices, comprising:
an upper guiding plate having a plurality of upper guiding holes;
a bottom guiding plate having a plurality of bottom guiding holes;
a plurality of vertical probes disposed between the upper guiding holes of the upper guiding plate and the bottom guiding holes of the bottom guiding plate; and
a temperature-adjusting module including at least one flow line configured to direct a fluid into a space between the upper guiding plate and the bottom guiding plate.

2. The probing apparatus for testing semiconductor devices of claim 1, wherein the flow line is configured to direct the fluid into the space between the upper guiding plate and the bottom guiding plate through an aperture of the upper guiding plate.

3. The probing apparatus for testing semiconductor devices of claim 1, wherein the flow line is configured to direct the fluid into the space through at least one side of the space.

4. The probing apparatus for testing semiconductor devices of claim 1, further comprising a plurality of spacers disposed between the upper guiding plate and the bottom guiding plate.

5. The probing apparatus for testing semiconductor devices of claim 1, further comprising a printed circuit board and a connector plate sandwiched between the upper guiding plate and the printed circuit board.

6. The probing apparatus for testing semiconductor devices of claim 5, wherein the connector plate includes a plurality of conductive patterns configured to electrically connect the vertical probes and the printed circuit board.

7. The probing apparatus for testing semiconductor devices of claim 5, wherein the printed circuit board includes a plurality of stacked laminates.

8. The probing apparatus for testing semiconductor devices of claim 1, wherein each of the vertical probes includes a connector end, a tip end, a linear body disposed between the connector end and the tip end, and at least one slot positioned on the linear body.

9. The probing apparatus for testing semiconductor devices of claim 1, wherein each of the vertical probes includes a connector end, a tip end, and a spring section disposed between the connector end and the tip end.

10. The probing apparatus for testing semiconductor devices of claim 1, wherein each of the vertical probes includes a connector end, a tip end and a buckling section disposed between the connector end and the tip end.

11. The probing apparatus for testing semiconductor devices of claim 11, wherein the fluid is gas, liquid or the combination thereof.

12. A probing apparatus for testing semiconductor devices, comprising:
an upper guiding plate having a plurality of upper guiding holes;
a bottom guiding plate having a plurality of bottom guiding holes and an upper surface facing the upper guiding plate;
a plurality of elastic probes disposed between the upper guiding holes of the upper guiding plate and the bottom guiding holes of the bottom guiding plate; and
a cleaning module including at least one flow line configured to direct a cleaning fluid to the upper surface of the bottom guiding plate, thereby removing particles from the upper surface.

13. The probing apparatus for testing semiconductor devices of claim 12, wherein the flow line is configured to direct the cleaning fluid to the upper surface of the bottom guiding plate through an aperture of the upper guiding plate.

14. The probing apparatus for testing semiconductor devices of claim 12, wherein the flow line is configured to direct the cleaning fluid to the upper surface of the bottom guiding plate through one side of a space between the upper guiding plate and the bottom guiding plate.

15. The probing apparatus for testing semiconductor devices of claim 12, further comprising a plurality of spacers disposed between the upper guiding plate and the bottom guiding plate.

16. The probing apparatus for testing semiconductor devices of claim 12, further comprising a printed circuit board and a connector plate sandwiched between the upper guiding plate and the printed circuit board.

17. The probing apparatus for testing semiconductor devices of claim 16, wherein the connector plate includes a plurality of conductive patterns configured to connect the elastic probes and the printed circuit board.

18. The probing apparatus for testing semiconductor devices of claim 16, wherein the printed circuit board includes a plurality of stacked laminates.

19. The probing apparatus for testing semiconductor devices of claim 12, wherein the fluid is gas, liquid or the combination thereof.

20. The probing apparatus for testing semiconductor devices of claim 12, wherein the elastic pin comprises:
a housing;
a spring with two ends positioned in the housing; and
two connecting pins connected to the two ends of the spring.
